(19) United States
(12) Patent Application Publication
(10) Pub. No.: US 2026/0040802 A1
(43) Pub. Date: Feb. 5, 2026

(54) DISPLAY DEVICE

(71) Applicant: LG Display Co., Ltd., Seoul (KR)

(72) Inventors: Seonghan HWANG, Paju-si (KR); Seungbum LEE, Paju-si (KR); Younghoon KIM, Paju-si (KR); Wonrae KIM, Paju-si (KR); Kyungkook JANG, Paju-si (KR); Jiyoon CHOI, Paju-si (KR)

(73) Assignee: LG Display Co., Ltd., Seoul (KR)

(21) Appl. No.: 19/230,730

(22) Filed: Jun. 6, 2025

(30) Foreign Application Priority Data
Aug. 1, 2024 (KR) 10-2024-0102257

(51) Int. Cl. H10K 59/80; H10K 59/122; H10K 59/40

(52) U.S. Cl. CPC H10K 59/8792; H10K 59/122; H10K 59/40

(57) ABSTRACT

A display device according to one or more examples includes a substrate, a display area including a plurality of sub-pixels, a non-display area outside the display area, an anode electrode disposed in each of the sub-pixels on the substrate, a bank disposed on the anode electrode, located at a boundary between adjacent sub-pixels, and overlapping a periphery of an upper surface of the anode electrode, and an optical pattern disposed between the periphery of the upper surface of the anode electrode and the bank, wherein the bank includes a black-based material.

### CROSS REFERENCE TO RELATED APPLICATION

The present application claims the benefit of and priority to Korean Patent Application No. 10-2024-0102257, filed Aug. 1, 2025, the entire contents of which are incorporated herein by reference for all purposes as if fully set forth herein.

### BACKGROUND

### 1. Technical Field

The present disclosure relates to a display device, and more specifically, for example, without limitation, to a display device in which a narrow bezel is enabled and crack propagation can be reduced or prevented.

### 2. Description of Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

Accordingly, the present disclosure is directed to a sound generating apparatus and a vehicle including the same that substantially obviate one or more of the issues due to limitations and disadvantages of the related art.

The description of related art should not be considered prior art merely because it is mentioned in or associated with this section. The description of related art includes information that describes one or more aspects of the subject technology, and the description in this section does not limit the scope of the invention.

### SUMMARY

Example embodiments of the present disclosure are directed to providing a display device in which an optical pattern including a higher refraction material than a bank can be formed on an upper surface of an anode electrode overlapping the bank to guide external light reflected from the anode electrode to the bank.

Example embodiments of the present disclosure are also directed to providing a display device in which a bank can include a black-based material to absorb external light guided to a bank.

Example embodiments of the present disclosure are also directed to providing a display device in which external light can be guided to a bank and absorbed, thereby reducing a reflectance due to an anode electrode.

Example embodiments of the present disclosure are also directed to providing a display device in which external light can be guided to a bank and absorbed, thereby preventing ring-shaped spots from occurring in an area in which an anode electrode overlaps the bank (or a part of a non-light-emitting area).

Aspects of the present disclosure are not limited to the above-described aspects, and other technical aspects may be inferred from the following embodiments.

According to one example embodiment, there is provided a display device including a substrate, a display area including a plurality of sub-pixels, a non-display area outside the display area, an anode electrode disposed on the substrate and located in each of the plurality of sub-pixels, a bank disposed on the anode electrode, located at a boundary between adjacent sub-pixels, and overlapping a periphery of an upper surface of the anode electrode, and an optical pattern disposed between the periphery of the upper surface of the anode electrode and the bank, wherein the bank includes a black-based material.

According to another example embodiment, there is provided a display device including a substrate, a display area including a plurality of sub-pixels, a non-display area outside the display area, an anode electrode disposed on the substrate and located in each of the plurality of sub-pixels, a bank disposed on the anode electrode, located at a boundary between adjacent sub-pixels, and overlapping a periphery of an upper surface of the anode electrode, an organic layer disposed on the anode electrode and the bank, a cathode electrode on the organic layer, an encapsulation part on the cathode electrode, a touch part disposed on the encapsulation part, a first touch conductive layer having a bridge electrode, and a second touch conductive layer having a sensor electrode and disposed on the first touch conductive layer, and a black matrix disposed at the boundary between the adjacent sub-pixels on the touch part and covering the bridge electrode and the sensor electrode, wherein a width of the black matrix is smaller than a width of the bank, and the display device further includes an optical pattern disposed between the periphery of the upper surface of the anode electrode and the bank.

Detailed matters of other example embodiments are included in the detailed description and accompanying drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view of a display device according to one example embodiment.

FIG. 2 is a cross-sectional view illustrating a bent state of a display panel according to FIG. 1.

FIG. 3 is a cross-sectional view along line A-A′ in FIG. 1.

FIG. 4 is a specific cross-sectional view of a light-emitting part of FIG. 3.

FIG. 5 is a specific cross-sectional view of a light-emitting part according to a modified example.

FIG. 6 is a cross-sectional view of a touch part according to FIG. 3.

FIG. 7 is a cross-sectional view along line B-B′ in FIG. 1.

FIG. 8 is a cross-sectional view along line C-C′ in FIG. 1.

FIG. 9 is an enlarged cross-sectional view of area Q1 in FIG. 3.

FIG. 10 is an enlarged cross-sectional view of area Q2 in FIG. 9.

FIG. 11 is an enlarged cross-sectional view of area Q2 in FIG. 9.

FIG. 12 is a cross-sectional view of a display device according to another example embodiment.

FIG. 13 is a cross-sectional view of a display device according to another example embodiment.

FIG. 14 is a cross-sectional view of a display device according to another example embodiment.

FIG. 15 is a cross-sectional view of a display device according to another example embodiment.

FIG. 16 is a cross-sectional view of a display device according to still another example embodiment.

FIG. 17 is a cross-sectional view of a display device according to still another example embodiment.

FIG. 18 is a cross-sectional view of a display device according to still another example embodiment.

FIG. 19 is a cross-sectional view of a display device according to yet another example embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Hereinafter, example embodiments will be described with reference to the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the present disclosure and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

The shapes (e.g., sizes, lengths, widths, heights, thicknesses, locations, radii, diameters, and areas), ratios, angles, numbers, and the like, which are illustrated in the drawings to describe various example embodiments of the present disclosure are merely given by way of example. Therefore, the present disclosure is not limited to the illustrations in the drawings.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

The same reference numerals indicate the same components. In addition, in the drawings, thicknesses, proportions, and dimensions of components can be exaggerated for effective description of technical contents. Scales of components shown in the drawings differ from the actual scale for convenience of description, and thus are not limited to the scales shown in the drawings.

In the present disclosure, when a first component (or an area, a layer, a portion, or the like) is described as “on,” “connected,” or “coupled to” a second component, it means that the first component may be directly connected/coupled to the second component or a third component may be disposed therebetween.

The term “and/or” includes all one or more combinations that may be defined by the associated configurations.

In construing an element, the element is construed as including an error range or tolerance range although there is no explicit description of such an error or tolerance range.

The terms, such as “below,” “lower,” “above,” “upper” and the like, may be used herein to describe a relationship between element(s) as illustrated in the drawings. It will be understood that the terms are spatially relative and based on the orientation depicted in the drawings.

Terms such as first, second “A,” “B,” “(a),” and “(b),” may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

It should be understood that term such as “includes” or “has” is intended to specify the presence of features, numbers, steps, operations, components, parts, or a combination thereof described in the present disclosure and does not preclude the presence or addition possibility of one or more other features, numbers, steps, operations, components, parts, or combinations thereof in advance.

Features of various embodiments of the present disclosure may be coupled or combined partially or entirely, various technological interworking and driving are made possible, and the embodiments may be implemented independently of each other or implemented together in an associated relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, a display device of the present disclosure will be described with reference to the accompanying drawings and example embodiments as follows.

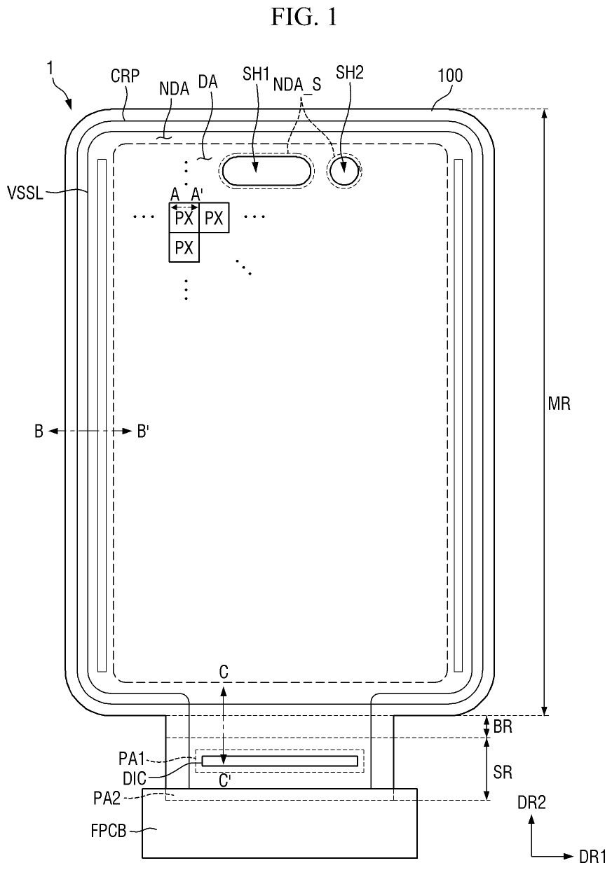

FIG. 1 is a plan view of a display device according to one example embodiment.

Referring to FIG. 1, a display device 1 according to one example embodiment may include a display panel 100. The display panel 100 may include a display area DA including a plurality of pixels PX and a non-display area NDA. As an example, the non-display area NDA may be extended from the display area DA. As an example, the non-display area NDA may fully or partially surround the display area DA. As an example, at least a portion of or the entirety of the non-display area NDA may be invisible from a front side of the display panel 100, for example, by being bent toward a rear side of the display panel 100, without being limited thereto. As an example, the flat surface shape of the display area DA may have a rectangular shape. However, the embodiments of the present disclosure are not limited thereto, and the flat surface shape of the display area DA may be a square, circular, elliptical, or other polygonal shapes, without being limited thereto. For example, the display area DA may have a rectangular shape with rounded corners, but is not limited thereto and may also have a rectangular shape with angled corners.

In example embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the example embodiments should be understood as indicating relative directions, and the embodiments are not limited to the described directions.

As an example, the display area DA may include short sides extending in the first direction DR1 and long sides extending in the second direction DR2, without being limited thereto. The non-display area NDA may surround the display area DA. The non-display area NDA may be disposed at one side and the other side of the display area DA in the first direction DR1 and one side and the other side of the display area DA in the second direction DR2. Embodiments are noy limited thereto. As an example, the display area DA may include no side, 3 sides or more than 4 sides. As an example, all sides of the display area DA may have the same length, without being limited thereto.

As an example, the display panel 100 may further include a sensor non-display area NDA_S and a sensor hole SH surrounded by the sensor non-display area NDA_S, without being limited thereto. The sensor hole SH1 and SH2 may be surrounded by the display area DA in a plan view. The sensor hole SH1 and SH2 may be, for example, two sensor holes as in FIG. 1, but the embodiments of the present disclosure are not limited thereto. For example, the sensor hole may be provided as one sensor hole. The two sensor holes SH1 and SH2 may include a sensor hole in which an infrared sensor is disposed and a sensor hole in which a camera sensor is disposed, but the embodiments of the present disclosure are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S. Embodiments are not limited thereto. As an example, there could be one, two or more senser holes. As an example, there could be two or more sensor non-display areas NDA_S. As an example, the sensor non-display area NDA_S may surround both of the sensor holes SH1 and SH2, without being limited thereto. As an example, the sensor non-display area NDA_S may be disposed between the two sensor holes SH1 and SH2. As an example, two the sensor non-display areas NDA_S may respectively surround the sensor holes SH1 and SH2. As an example, the sensor non-display area NDA_S and a sensor hole SH may be omitted depending on the design.

As an example, a gate driving unit GIP may be disposed in the non-display area NDA located at one side and/or the other side of the display area DA in the first direction DR1, without being limited thereto. As an example, a low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be located outside the gate driving unit GIP on the non-display area NDA, and disposed to surround the display area DA. Embodiments are not limited thereto. As an example, the low-potential voltage line VSSL may be disposed inside the gate driving unit GIP on the non-display area NDA. As an example, the low-potential voltage line VSSL may be disposed to overlap the gate driving unit GIP. As an example, the gate driving unit may not be disposed on the non-display area NDA, but may be separately disposed on a separate panel and connected to the display panel 100, for example, in a tape automated bonding (TAB) method, a chip on glass (COG) method, a chip on panel (COP) method, or a chip on film (COF) method, without being limited thereto.

The non-display area NDA located at the other side of the display area DA in the second direction DR2 may extend further from a central portion or a periphery portion of the other side of the display area DA toward outside of the display area DA in the second direction DR2. A width of the non-display area NDA in the first direction DR1 further extending from the central portion of the other side of the display area DA toward the outside of the display area DA in the second direction DR2 may be smaller than a width of the non-display area NDA in the first direction DR1 adjacent to the other side of the display area DA in the second direction DR2, without being limited thereto.

A display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the outside of the display area DA in the second direction DR2 may form the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and the printed circuit board FPCB. The data driving unit DIC may be disposed in the first pad area PA1, and the printed circuit board FPCB may be attached to the second pad area PA2. A plurality of pads connected to the data driving unit DIC or the printed circuit board FPCB may be disposed in each of the first pad area PA1 and the second pad area PA2. The data driving unit DIC may be configured, for example, in the form of a driving chip (IC), but is not limited thereto. In one example embodiment, a case in which the data driving unit DIC is disposed by a chip on plastic method in which the data driving unit DIC is directly mounted on the display panel 100 is described, but the embodiments of the present disclosure are not limited thereto, and the data driving unit DIC may be disposed by a chip on glass or chip on film method, without being limited thereto.

The display panel 100 according to one example embodiment may further include a crack sensing pattern CRP surrounding the low-potential voltage line VSSL. As an example, the crack sensing pattern CSP may be disposed to completely surround the display area DA as illustrated in FIG. 1, without being limited thereto. For example, the crack sensing pattern CSP may be disposed outside the low-potential voltage line VSSL. However, the embodiments of the present disclosure are not limited thereto, and as an example, a part of the crack sensing pattern CSP may not be disposed in the non-display area NDA at the other side of the display area DA in the second direction DR2, or at any position on the non-display area NDA.

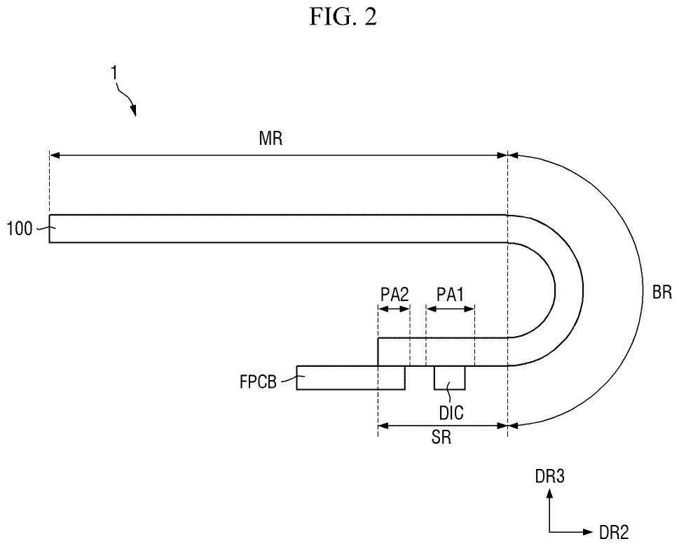

FIG. 2 is a cross-sectional view illustrating a bent state of a display panel according to FIG. 1.

Referring to FIG. 2, the bending region BR of the display panel 100 of the display device 1 according to one example embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

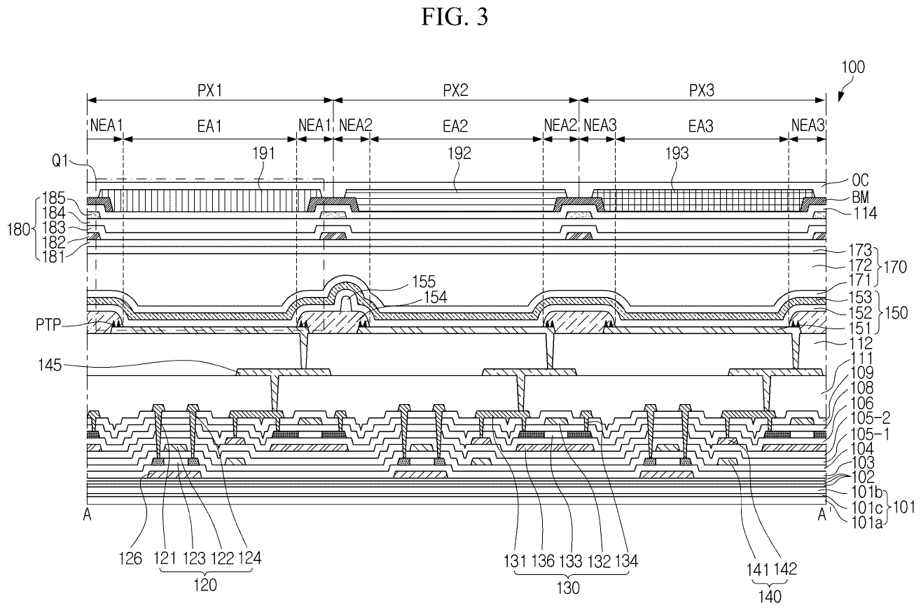

FIG. 3 is a cross-sectional view along line A-A′ in FIG. 1.

Referring to FIG. 3, the pixel PX (see FIG. 1) of the display panel 100 may include a plurality of sub-pixels PX1, PX2, and PX3. The first sub-pixel PX1 may be a red sub-pixel, the second sub-pixel PX2 may be a green sub-pixel, and the third sub pixel PX3 may be a blue sub-pixel, but the embodiments of the present disclosure are not limited thereto. In some embodiments, the pixel PX further includes a fourth sub-pixel, and the fourth sub-pixel may be a white sub-pixel, but the embodiments of the present disclosure are not limited thereto. As an example, the pixel PX (see FIG. 1) of the display panel 100 may include two, four or more subpixels. As an example, the plurality of subpixels included in one pixel may emit light of different colors, or two or more of the plurality of subpixels included in one pixel may emit light of the same color. As an example, a subpixel emitting light of a color other than red, green, blue, white may be alternatively or additionally included.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184. Embodiments are not limited thereto. As an example, one or more above-mentioned components may be omitted, and/or one or more additional components may be further included.

The substrate 101 may be a rigid substrate or a flexible substrate. As an example, the substrate 101 may be a transparent substrate or an opaque substrate. As an example, the substrate 101 may include glass, plastic, or a flexible polymer film, without being limited thereto. As an example, the substrate 101 may include one or more plastic materials. As an example, the substrate 101 may include one or more of polyethylene terephthalate(PET), polycarbonate(PC), acrylonitrile-butadiene-styrene copolymer(ABS), polyimide(PI) film, without being limited thereto. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The buffer layer 102 may be disposed on the substrate 101. The buffer layer 102 can reduce, minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present disclosure are not limited thereto.

A first light-shielding layer 126 may be optionally disposed on the buffer layer 102. The first light-shielding layer 126 can reduce or prevent light from transmitting a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto. As an example, the light-shielding layer 126 may be omitted dependent on the design.

The first insulating layer 103 may be disposed on the buffer layer 102 and the first light-shielding layer 126. The first insulating layer 103 can reduce or prevent a short circuit between a component of the first thin film transistor 120 and the first light-shielding layer 126. The first insulating layer 103 may be formed of the same material as or a different material from the buffer layer 102, but the embodiments of the present disclosure are not limited thereto. For example, the first insulating layer 103 may be formed of an inorganic insulation material, such as silicon nitride (SiNₓ) or silicon oxide (SiOₓ), but the embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), a silicon-based semiconductor material, such as amorphous silicon, polycrystalline silicon, a compound semiconductor, and an oxide semiconductor, etc., but the embodiments of the present disclosure are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, as an example, a driving transistor may be formed of the polycrystalline semiconductor layer, without being limited thereto.

The second insulating layer 104 may be disposed on the first semiconductor layer 123. The second insulating layer 104 may be formed of the same material as or a different material from the first insulating layer 103 and can reduce or prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but the embodiments of the present disclosure are not limited thereto. The first gate electrode 122 may be disposed along with a gate line, without being limited thereto.

The third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present disclosure are not limited thereto. For example, the 3-1 insulating layer 105-1 may include silicon oxide (SiOₓ), and the 3-2 insulating layer 105-2 may include silicon nitride (SiNₓ), but the embodiments of the present disclosure are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a conductive material (e.g., a metallic material). For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 may be disposed along with a data line, without being limited thereto. For example, the data line may be formed of the same material as the first source electrode 121 and the first drain electrode 124 and formed on the same layer as the first source electrode 121 and the first drain electrode 124, but the embodiments of the present disclosure are not limited thereto. As an example, the data line may be formed of a different material from the first source electrode 121 and the first drain electrode 124 and/or may be formed on a different layer from the first source electrode 121 and the first drain electrode 124.

A storage electrode 140 may be disposed to be spaced apart from the first thin film transistor 120. The storage electrode 140 may include a first storage electrode 141 and a second storage electrode 142.

As an example, the first storage electrode 141 may be formed of the same material as or a different material from the first gate electrode 122 and/or disposed on the same layer as or a different layer from the first gate electrode 122, but the embodiments of the present disclosure are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance, without being limited thereto. The second storage electrode 142 may be formed of the same material as or a different material from the first storage electrode 141, but the embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as or a different layer from the second storage electrode 142, without being limited thereto. As an example, the second light-shielding layer 136 may be omitted depending on the design.

The second light-shielding layer 136 can reduce or prevent light from traveling to the second semiconductor layer 133 similar to the first light-shielding layer 126, thereby extending the life of the second thin film transistor 130. For example, the second semiconductor layer 133 may be disposed to overlap the second light-shielding layer 136.

The fourth insulating layer 106 may be disposed on the second light-shielding layer 136. The fourth insulating layer 106 may be formed of the same material as the first insulating layer 103, the second insulating layer 104, or the third insulating layers 105-1 and 105-2, but the embodiments of the present disclosure are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), a silicon-based semiconductor material, such as amorphous silicon, polycrystalline silicon, a compound semiconductor, and an oxide semiconductor, etc., but the embodiments of the present disclosure are not limited thereto.

The fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 may be disposed on the fifth insulating layer 108.

The second gate electrode 132 may be formed of the same material as the first gate electrode 122, without being limited thereto. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

The sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 may be disposed on the sixth insulating layer 109, without being limited thereto. As an example, the first source electrode 121 and the first drain electrode 124 may be disposed on a different layer from the second source electrode 131 and the second drain electrode 134.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present disclosure are not limited thereto.

The first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material, and/or an inorganic material. For example, the first protective layer 111 may be formed of an organic material containing an acrylic resin, an epoxy resin, a phenolic resin, a polyamide resin, or a polyimide resin, but the embodiments of the present disclosure are not limited thereto.

The second protective layer 112 may be disposed on the first protective layer 111. The second protective layer 112 may be formed of the same material as the first protective layer 111, or may be formed of a different material from the first protective layer 111, but the embodiments of the present disclosure are not limited thereto.

In some example embodiments, a third protective layer may be further disposed on an upper surface of the second protective layer 112, but the embodiments of the present disclosure are not limited thereto.

As an example, a connection electrode 145 may be disposed between the first protective layer 111 and the second protective layer 112, without being limited thereto.

The connection electrode 145 may electrically connect the first thin film transistor 120 to the light-emitting part 150. The connection electrode 145 may be formed of the same material as or a different material from the first source electrode 121 and the first drain electrode 124, but the embodiments of the present disclosure are not limited thereto. As an example, the connection electrode 145 may be omitted. As an example, the first thin film transistor 120 may be directly connected to the light-emitting part 150 without any connection electrode, without being limited thereto.

The connection electrode 145 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. As an example, the anode electrode 151 may be a reflective electrode that reflects light, but the embodiments of the present disclosure are not limited thereto. The anode electrode 151 may include a conductive material. As an example, the anode electrode 151 may include a metallic material with high reflectivity, such as a stacking structure (Ti/Al/Ti) of aluminum (Al) and titanium (Ti), a stacking structure (ITO/AI/ITO) of aluminum (Al) and indium tin oxide (ITO), or an APC alloy and may be formed of a single layer or multiple layers, but the embodiments of the present disclosure are not limited thereto.

The organic layer 152 may be disposed on the anode electrode 151. The organic layer 152 may include one or more light-emitting structures (or light-emitting elements) stacked on the anode electrode 151 in the order or reverse order of a hole transfer layer and an electron transfer layer, without being limited thereto. For example, the hole transfer layer may include a hole transporting layer, a hole injecting layer, an electron blocking layer, a p-type charge generation layer, etc., but the embodiments of the present disclosure are not limited thereto. For example, the electron transfer layer may include an electron transporting layer, an electron injecting layer, a hole blocking layer, an n-type charge generation layer, etc., but the embodiments of the present disclosure are not limited thereto. As an example, one or more of the above-mentioned layers could be omitted depending on the design. The organic layer 152 may be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one example embodiment of the present disclosure may include an organic light-emitting layer. The organic layer 152 may include a red light-emitting layer, a green light-emitting layer, and a blue light-emitting layer. The organic layer 152 may be a white light-emitting layer, but the embodiments of the present disclosure are not limited thereto. Hereinafter, a specific structure of the organic layer 152 according to one example embodiment will be described.

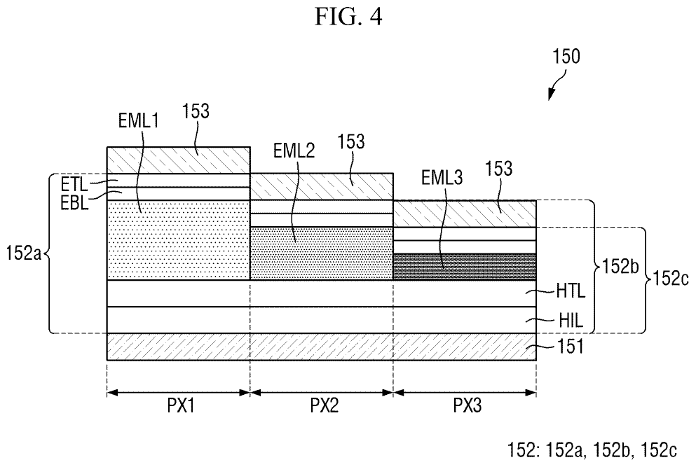

FIG. 4 is a specific cross-sectional view of a light-emitting part of FIG. 3.

Referring to FIG. 4, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present disclosure are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3, without being limited thereto. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present disclosure are not limited thereto.

A hole injecting layer HIL may be disposed on the anode electrode 151. The hole injecting layer HIL may be located between the anode electrode 151 and the light-emitting layers EML1, EML2, and EML3. The hole injecting layer HIL may be formed integrally across the sub-pixels PX1, PX2, and PX3, or may be separately formed for each of the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl) phenyl)-9H-fluoren-2-amine, etc., but the embodiments of the present disclosure are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be formed integrally across the sub-pixels PX1, PX2, and PX3, or may be separately formed for each of the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA (4,4′,4″-Tris (N-3-methylphenyl-N-phenyl-amino)-triphenylamine), but the embodiments of the present disclosure are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

The thicknesses of each light-emitting layer EML1, EML2, or EML3 may be different. For example, the first light-emitting layer EML1 may be formed in a thickness of 600 to 800 Å, the second light-emitting layer EML2 may be formed in a thickness of 300 to 500 Å, and the third light-emitting layer EML3 may be formed in a thickness of 100 to 300 Å, but the embodiments of the present disclosure are not limited thereto.

Each of the first light-emitting layer EML1, the second light-emitting layer EML2, and the third light-emitting layer EML3 may include a material that may emit light in the visible light range by receiving and combining holes and electrons.

An electron blocking layer EBL may be disposed on each light-emitting layer EML1, EML2, or EML3. The electron blocking layer EBL may be disposed integrally across the sub-pixels PX1, PX2, and PX3, or may be separately formed for each of the sub-pixels PX1, PX2, and PX3.

An electron transporting layer ETL may be disposed on the electron blocking layer EBL. The electron transporting layer ETL may be disposed integrally across the sub-pixels PX1, PX2, and PX3, or may be separately formed for each of the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 may be disposed on the electron transporting layer ETL.

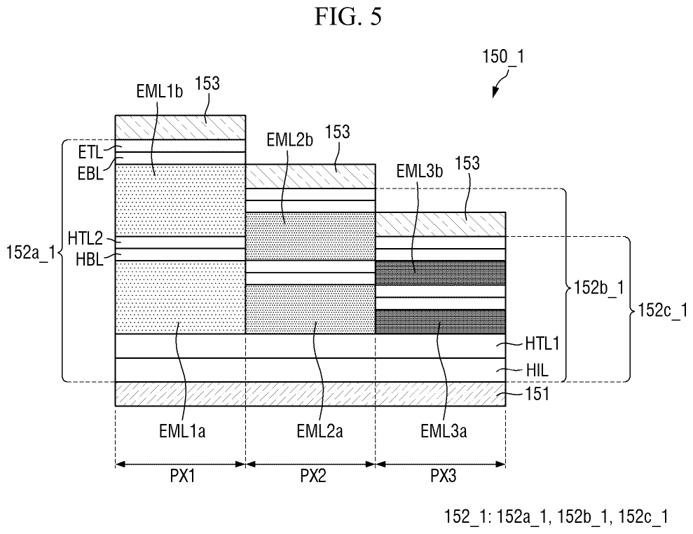

FIG. 5 is a specific cross-sectional view of a light-emitting part according to a modified example.

Referring to FIGS. 4 and 5, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers of each organic layer 152a_1, 152b_1, or 152c_1 may be physically separated, but the lower layers and upper layers of the light-emitting layers may be formed integrally across the sub-pixels PX1, PX2, and PX3, without being limited thereto. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present disclosure are not limited thereto. In addition, the light-emitting layers of each organic layer 152a_1, 152b_1, or 152c_1 may be provided as two or more light-emitting layers.

The hole injecting layer HIL may be disposed on the anode electrode 151. The hole injecting layer HIL may be located between the anode electrode 151 and the light-emitting layers EML1a, EML2a, and EML3a. The hole injecting layer HIL may be formed integrally across the sub-pixels PX1, PX2, and PX3, or may be separately formed for each of the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl) phenyl)-9H-fluoren-2-amine, etc., but the embodiments of the present disclosure are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be formed integrally across the sub-pixels PX1, PX2, and PX3, or may be separately formed for each of the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA (4,4′,4″-Tris (N-3-methylphenyl-N-phenyl-amino)-triphenylamine), but the embodiments of the present disclosure are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a may be the same as each of the light-emitting layers EML1, EML2, and EML3 of FIG. 4, without being limited thereto.

A thicknesses of each light-emitting layer EML1a, EML2a, or EML3a may be different. For example, the 1-1 light-emitting layer EML1a may be formed in a thickness of 600 to 800 Å, the 2-1 light-emitting layer EML2a may be formed in a thickness of 300 to 500 Å, and the 3-1 light-emitting layer EML3a may be formed in a thickness of 100 to 300 Å, but the embodiments of the present disclosure are not limited thereto.

A hole blocking layer HBL may be disposed on each light-emitting layer EML1a, EML2a, or EML3a. The hole blocking layer HBL may be disposed integrally across the sub-pixels PX1, PX2, and PX3, or may be separately formed for each of the sub-pixels PX1, PX2, and PX3.

A second hole transporting layer HTL2 may be disposed on the hole blocking layer HBL. The second hole transporting layer HTL2 may be disposed between the hole blocking layer HBL and the light-emitting layers EML1b, EML2b, and EML3b. The second hole transporting layer HTL2 may be formed integrally across the sub-pixels PX1, PX2, and PX3, or may be separately formed for each of the sub-pixels PX1, PX2, and PX3. A material of the second hole transporting layer HTL2 may be the same as a material of the first hole transporting layer HTL1, but the embodiments of the present disclosure are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a, without being limited thereto.

A thicknesses of each light-emitting layer EML1b, EML2b, or EML3b may be different. For example, the 1-2 light-emitting layer EML1b may be formed in a thickness of 600 to 800 Å, the 2-2 light-emitting layer EML2b may be formed in a thickness of 300 to 500 Å, and the 3-2 light-emitting layer EML3b may be formed in a thickness of 100 to 300 Å, but the embodiments of the present disclosure are not limited thereto. As an example, the thickness of the light-emitting layer EML1b, EML2b, or EML3b may be the same as the thickness of the light-emitting layer EML1a, EML2a, or EML3a, or the thickness of the light-emitting layer EML1b, EML2b, or EML3b may be different from the thickness of the light-emitting layer EML1a, EML2a, or EML3a.

An electron blocking layer EBL may be disposed on each light-emitting layer EML1b, EML2b, or EML3b. The electron blocking layer EBL may be disposed integrally across the sub-pixels PX1, PX2, and PX3, or may be separately formed for each of the sub-pixels PX1, PX2, and PX3.

An electron transporting layer ETL may be disposed on the electron blocking layer EBL. The electron transporting layer ETL may be disposed integrally across the sub-pixels PX1, PX2, and PX3, or may be separately formed for each of the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The cathode electrode 153 may be disposed on the electron transporting layer ETL.

Referring back to FIG. 3, the cathode electrode 153 may be disposed on the organic layer 152. The cathode electrode 153 may be a transparent electrode that transmits light, but the embodiments of the present disclosure are not limited thereto. For example, the cathode electrode 153 may include a transparent conductive material, such as indium tin oxide (ITO) or indium zinc oxide (IZO), or a metal that transmits visible light, but the embodiments of the present disclosure are not limited thereto.

A bank 154 may be disposed to expose the anode electrode 151. The bank 154 may define openings (or the light-emitting areas EA1, EA2, and EA3) of the sub-pixels PX1, PX2, and PX3 and may be disposed to cover an edge portion (or a periphery) of the anode electrode 151. As an example, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. As an example, each non-light-emitting area NEA1, NEA2, or NEA3 may correspond to a boundary between adjacent sub-pixels PX1, PX2, and PX3.

The bank 154 may include a black-based material. For example, the bank 154 may be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 may be a black bank. When the bank 154 is formed of a material containing black pigment or black dye, it is possible to shield external light or light reflected from the outside, thereby further increasing the luminance of the display device.

According to the display device 1 according to one example embodiment, an optical pattern PTP may be disposed between the anode electrode 151 and the bank 154. As an example, the optical pattern PTP may be formed directly on an upper surface of the anode electrode 151. Alternatively, one or more pattern may be interposed between the optical pattern PTP and the anode electrode 151. The optical pattern PTP may come into direct contact with the bank 154. As an example, no pattern PTP is disposed outside the bank 154, without being limited thereto. As an example, the optical pattern PTP may be completely covered by the bank 154, without being limited thereto. The optical pattern PTP may serve to reduce the reflectance of the anode electrode 151. The function of the optical pattern PTP will be described below.

A spacer 155 may be further disposed on the bank 154. The spacer 155 may be formed of the same material as the bank 154, but the embodiments of the present disclosure are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the present disclosure are not limited thereto. In some example embodiments, the bank 154 and the spacer 155 may be formed of the same material and formed simultaneously through a halftone mask, but the embodiments of the present disclosure are not limited thereto.

The organic layer 152 may be disposed on the anode electrode 151, the bank 154, and the spacer 155. The cathode electrode 153 may be disposed on the organic layer 152.

The encapsulation part 170 may be disposed on the cathode electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present disclosure are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some example embodiments, a touch organic layer may be further disposed on the second touch conductive layer, but the embodiments of the present disclosure are not limited thereto. As an example, one or more of above-mentioned components of the touch part 180 may be omitted depending on the design, and/or one or more additional components may be further included. As an example, the entire touch part 180 may be omitted depending on the design.

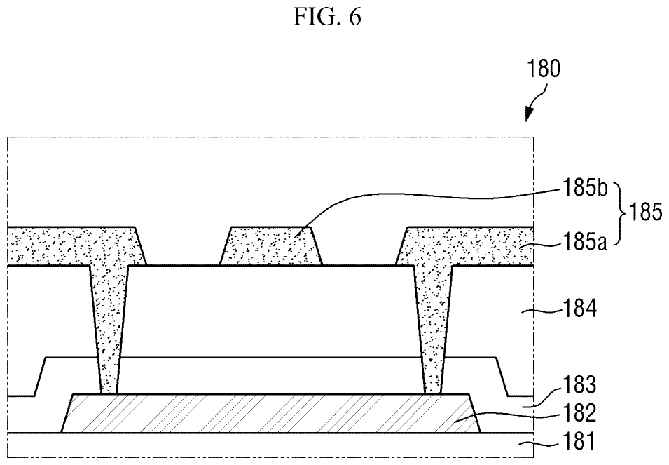

FIG. 6 is a cross-sectional view of a touch part according to FIG. 3.

Referring to FIGS. 3 and 6, the touch buffer layer 181 may be disposed on the encapsulation part 170. For example, the touch buffer layer 181 may be disposed on the third encapsulation layer 173. The touch buffer layer 181 may be formed of the same material as the buffer layer 102, but the embodiments of the present disclosure are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be reduced or prevented from being visible from the outside. Embodiments are not limited thereto. As an example, the bridge electrode 182 and the sensor electrode 185 may be disposed to at least partially overlap the sub-pixels PX1, PX2, and PX3. As an example, the bridge electrode 182 and the sensor electrode 185 may be opaque electrodes, transparent electrodes, or mesh-type electrodes, without being limited thereto.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can reduce or prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present disclosure are not limited thereto. The second touch insulating layer 184 may include an organic insulation material, but the embodiments of the present disclosure are not limited thereto, and the second touch insulating layer 184 may include the same material as the first touch insulating layer 183. As an example, at least one of the first touch insulating layer 183 and the second touch insulating layer 184 may be omitted, and/or one or more insulating layers may be further included.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1. Embodiments are not limited thereto. As an example, the first sensor electrode 185a and/or the second sensor electrode 185b may extend in a direction between the first direction DR1 and the second direction DR2, without being limited thereto. As an example, although it is illustrated and described that the first sensor electrode 185a and/or the second sensor electrode 185b are disposed above the bridge electrode 182, embodiments are not limited thereto. As an example, the bridge electrode 182 may be disposed above the first sensor electrode 185a and/or the second sensor electrode 185b, without being limited thereto.

The bridge electrode 182 may be electrically connected to the first sensor electrode 185a through contact holes formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the sensor electrode 185 and the bridge electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto. As an example, the sensor electrode 185 and the bridge electrode 182 may be formed of transparent conducive materials, without being limited thereto.

A filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the present disclosure are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be reduced or prevented from being visible from the outside. For example, a width of the black matrix BM may be smaller than a width of the bank 154. Embodiments are not limited thereto. As an example, the black matrix BM may not cover the bridge electrode 182 and the sensor electrode 185. As an example, the black matrix BM may be omitted depending on the design.

As an example, the color filters 191, 192, and 193 may be disposed on or under the black matrix BM, without being limited thereto.

The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, the second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present disclosure are not limited thereto.

For example, each color filter 191, 192, or 193 may come into direct contact with side and upper surfaces of the black matrix BM, or another pattern may be disposed between the color filter 191, 192, or 193 and the black matrix BM. For example, each color filter 191, 192, or 193 may be spaced apart from the boundaries of adjacent sub-pixels PX1, PX2, and PX3, but the embodiments of the present disclosure are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material, without being limited thereto.

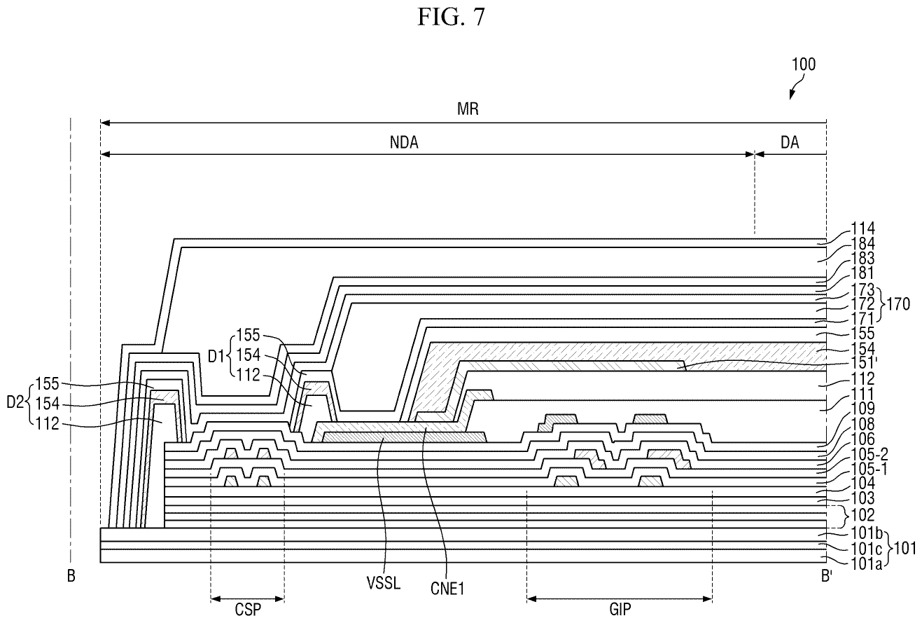

FIG. 7 is a cross-sectional view along line B-B′ in FIG. 1.

Referring to FIG. 7, at least one of the panel inorganic layers 102, 103, 104, 105-1, 105-2, 106, 108, and 109 may not extend to the end portion of the substrate 101. As an example, the at least one of the panel inorganic layers 102, 103, 104, 105-1, 105-2, 106, 108, and 109 may expose the end portion of the substrate 101, but the embodiments of the present disclosure are not limited thereto.

The display panel 100 according to one example embodiment may further include the crack sensing pattern CSP, the low-potential voltage line VSSL, and the gate driving unit GIP. As described above in FIG. 1, the low-potential voltage line VSSL may be located between the crack sensing pattern CSP and the display area DA, and the gate driving unit GIP may be located between the low-potential voltage line VSSL and the display area DA.

For example, as illustrated in FIG. 7, the gate driving unit GIP may be formed of a conductive layer located on the same layer as the first gate electrode 122 (see FIG. 3), a conductive layer located on the same layer as the second light-shielding layer 136 (see FIG. 3), or a conductive layer located on the same layer as the first source electrode 121, but the embodiments of the present disclosure are not limited thereto.

For example, the crack sensing pattern CSP may be disposed between a first dam D1 and a second dam D2, without being limited thereto. As an example, the crack sensing pattern CSP may be formed of a conductive layer located on the same layer as the first gate electrode 122 (see FIG. 3) or a conductive layer located on the same layer as the second light-shielding layer 136 (see FIG. 3), but the embodiments of the present disclosure are not limited thereto. For example, the crack sensing pattern CSP may include a conductive layer located on the same layer as the first source electrode 121, or may include one or more conductive layers located on any other layer, but the embodiments of the present disclosure are not limited thereto.

As an example, the low-potential voltage line VSSL may be disposed between the crack sensing pattern CSP and the gate driving unit GIP, without being limited thereto. The low-potential voltage line VSSL may be formed of a conductive layer located on the same layer as the first source electrode 121, or may be formed of one or more conductive layers located on any other layer, but the embodiments of the present disclosure are not limited thereto.

As an example, the first protective layer 111 may cover the gate driving unit GIP, partially cover one end portion of the low-potential voltage line VSSL, and expose the other end portion of the low-potential voltage line VSSL, without being limited thereto. In the present disclosure, the one end portion may refer to an area of a certain component, which is located in a direction from the non-display area NDA toward the display area DA, and the other end portion may refer to an area of the certain component, which is located in a direction from the display area DA toward the non-display area NDA.

As an example, a first connection electrode CNE1 located on the same layer as the connection electrode 145 may be disposed on the first protective layer 111, without being limited thereto. As an example, the first connection electrode CNE1 may be directly connected to an area of the low-potential voltage line VSSL, which is exposed by the first protective layer 111, without being limited thereto. The first connection electrode CNE1 may cover the other end portion of the low-potential voltage line VSSL, but the embodiments of the present disclosure are not limited thereto. As an example, the first connection electrode CNE1 may cover the entirety or at least a portion of the area of the low-potential voltage line VSSL, which is exposed by the first protective layer 111. As an example, the first connection electrode CNE1 may be omitted depending on the design.

The second protective layer 112 may be disposed on the first connection electrode CNE1. The second protective layer 112 may come into direct contact with and cover one end portion of the first connection electrode CNE1 and expose the other end portion of the first connecting electrode CNE1. As an example, the second protective layer 112 may form a first layer of the first dam D1 and/or a first layer of the first dam D1, without being limited thereto. The first dam D1 may overlap, for example, the low-potential voltage line VSSL and cover the other end portion of the low-potential voltage line VSSL. The first dam D1 may come into direct contact with the first connection electrode CNE1 and cover the other end portion of the first connection electrode CNE1, without being limited thereto. The second protective layer 112 forming the first layer of the second dam D2 may come into direct contact with the exposed side surfaces of at least one of the panel inorganic layers 102, 103, 104, 105, 106, 107, and 109 and may come into direct contact with the upper surface of the substrate 101, but the embodiments of the present disclosure are not limited thereto. The second protective layer 112 may overlap the gate driving unit GIP. In the present disclosure, the dam is, for example, provided as two dams, but the dam may be provided as three or more dams or one dam.

A low-potential connection electrode 151′ may be disposed on the first connection electrode CNE1 exposed by the second protective layer 112 and the second protective layer 112. As an example, the low-potential connection electrode 151′ may be located on the same layer as the anode electrode 151 (see FIG. 3), without being limited thereto. As an example, the low-potential connection electrode 151′ may be disposed on the first connection electrode CNE1 exposed by the second protective layer 112 and/or the low-potential voltage line VSSL exposed by the first connection electrode CNE1 and/or the second protective layer 112, without being limited thereto. The low-potential connection electrode 151′ may be electrically connected to the first connection electrode CNE1 exposed by the second protective layer 112. The low-potential connection electrode 151′ may be electrically connected to the cathode electrode 153 described above in FIG. 3.

As an example, the bank 154 may be disposed on the low-potential connection electrode 151′ and the second protective layer 112. The bank 154 may overlap the gate driving unit GIP, overlap the low-potential connection electrode 151′, and cover the other end portion of the low-potential connection electrode 151′, without being limited thereto. The bank 154 may completely cover the low-potential connection electrode 151′, but the embodiments of the present disclosure are not limited thereto. The bank 154 may expose a central portion and the other end portion of the first connection electrode CNE1, but the embodiments of the present disclosure are not limited thereto. The bank 154 may form a second layer of the first dam D1 and a second layer of the second dam D2, without being limited thereto. In each dam D1 or D2, the bank 154 may overlap the second protective layer 112 forming the first layer and completely cover the second protective layer 112, or may exposed at least a portion of the second protective layer 112, but the embodiments of the present disclosure are not limited thereto. In the second dam D2, the bank 154 may come into contact with the side surfaces of the second protective layer 112 and the upper surface of the substrate 101, but the embodiments of the present disclosure are not limited thereto. As an example, the bank 154 may expose at least a portion of the side surfaces of the second protective layer 112 and/or may not contact the upper surface of the substrate 101, without being limited thereto.

The spacer 155 may be disposed on the bank 154. The spacer 155 may overlap the gate driving unit GIP. As an example the spacer 155 may form a third layer of the dam D1 or D2, without being limited thereto, or may not be formed in the dam D1 or D2. The spacer 155 forming the third layer of each dam D1 or D2 may overlap the bank 154 forming the second layer. As an example, the spacer 155 forming the third layer of each dam D1 or D2 may completely cover the bank 154, but the embodiments of the present disclosure are not limited thereto. In the second dam D2, the spacer 155 may come into contact with the side surfaces of the bank 154 and the upper surface of the substrate 101, but the embodiments of the present disclosure are not limited thereto. As an example, the spacer 155 may expose at least a portion of the side surfaces of the bank 154 and/or may not contact the upper surface of the substrate 101, without being limited thereto.

The encapsulation part 170 may be disposed on the spacer 155. The first encapsulation layer 171 may extend to the gate driving unit GIP, the low-potential voltage line VSSL, the first dam D1, and the second dam D2 and cover an outer surface of the second dam D2. As an example, the second encapsulation layer 172 may end at the first dam D1, or may end between the first dam D1 and the second dam D2, without being limited thereto. The second encapsulation layer 172 may overlap the gate driving unit GIP and the low-potential voltage line VSSL. The third encapsulation layer 173 may extend to the gate driving unit GIP, the low-potential voltage line VSSL, the first dam D1, and the second dam D2 and come into direct contact with the first encapsulation layer 171 on the first dam D1, the crack sensing pattern CSP, and/or the second dam D2. As an example, the first encapsulation layer 171 and/or the third encapsulation layer 173 may come into contact the upper surface of the substrate 101, without being limited thereto. As an example, the first encapsulation layer 171 and/or the third encapsulation layer 173 may come into contact the upper surface of the substrate 101 while exposing at least a portion of the upper surface of the substrate 101, without being limited thereto.

The touch buffer layer 181 and the first touch insulating layer 183 may extend to the gate driving unit GIP, the low-potential voltage line VSSL, the first dam D1, and the second dam D2 and cover the outer surface of the second dam D2. The second touch insulating layer 184 may extend to the gate driving unit GIP, the low-potential voltage line VSSL, the first dam D1, and the crack sensing pattern CSP and end on the second dam D2, but the embodiments of the present disclosure are not limited thereto. As an example, the touch buffer layer 181 and the first touch insulating layer 183 may come into contact the upper surface of the substrate 101, without being limited thereto.

The filter insulating layer 184 may extend to the gate driving unit GIP, the low-potential voltage line VSSL, the first dam D1, and the second dam D2 and come into direct contact with an outer surface of the second touch insulating layer 184 and/or the upper surface of the substrate 101, but the embodiments of the present disclosure are not limited thereto.

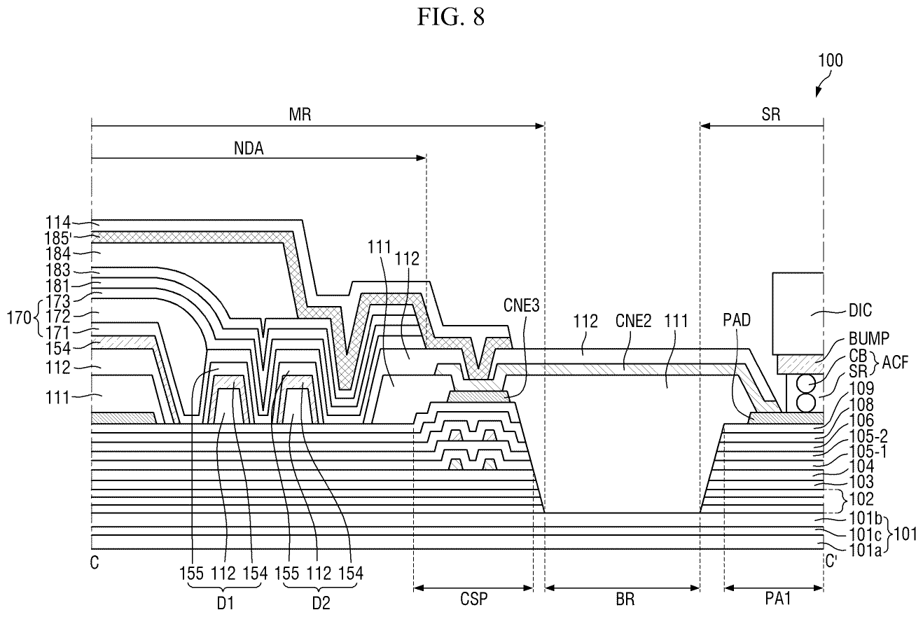

FIG. 8 is a cross-sectional view along line C-C′ in FIG. 1.

Referring to FIGS. 3, 7, and 8, the bending region BR may be disposed between the sub-region SR and the crack sensing pattern CSP. In the bending region BR, the panel inorganic layers 102, 103, 104, 105, 106, 107, and 109 may be removed to expose the upper surface of the substrate 101, without being limited thereto.

As an example, a pad electrode PAD may be disposed in the first pad area PA1, and a third connection electrode CNE3 may be disposed on the crack sensing pattern CSP. As an example, the pad electrode PAD may be disposed on the same layer as the first source electrode 121 (see FIG. 3), and/or the third connection electrode CNE3 may be disposed on the same layer as the first source electrode 121 (see FIG. 3), without being limited thereto.

The first protective layer 111 may be disposed on the pad electrode PAD and the third connection electrode CNE3. The first protective layer 111 may be disposed in the bending region BR. As an example, the first protective layer 111 may come into direct contact with the upper surface of the substrate 101 and in the bending region BR, without being limited thereto. As an example, the first protective layer 111 may come into direct contact with the side surfaces of the panel inorganic layers 102, 103, 104, 105, 106, 107, and 109, without being limited thereto.

A second connection electrode CNE2 may be disposed on the first protective layer 111. As an example, the second connection electrode CNE2 may be disposed on the same layer as the connection electrode 145 (see FIG. 3). The second connection electrode CNE2 may electrically connect the pad electrode PAD to the third connection electrode CNE3. The second connection electrode CNE2 may be disposed on the bending region BR and may also be disposed on the first pad area PA1 and the crack sensing pattern CSP.

The data driving unit DIC may be disposed on or connected to the pad electrode PAD. As an example, the data driving unit DIC may include a bump BUMP, an anisotropic conductive film ACF may be disposed between the pad electrode PAD and the bump BUMP, and the anisotropic conductive film ACF may electrically connect the pad electrode PAD to the bump BUMP, without being limited thereto. The anisotropic conductive film ACF may include a resin SR and a plurality of conductive balls CB dispersed in the resin SR. The pad electrode PAD and the bump BUMP may be electrically connected through the conductive balls CB.

As an example, the second protective layer 112 may be disposed on the second connection electrode CNE2, without being limited thereto. The second protective layer 112 may expose the pad electrode PAD.

The first and second encapsulation layers 171 and 173 of the encapsulation part 170 may extend until before the bending region BR. For example, the first and second encapsulation layers 171 and 173 may extend until before the crack sensing pattern CSP, but the embodiments of the present disclosure are not limited thereto, and the first and second encapsulation layers 171 and 173 may also overlap the crack sensing pattern CSP. The first and second encapsulation layers 171 and 173 may not be disposed in the bending region BR.

The touch buffer layer 181 and the first touch insulation layer 183 may extend until before the bending region BR. For example, the touch buffer layer 181 and the first touch insulating layer 183 may extend until before the crack sensing pattern CSP, but the embodiments of the present disclosure are not limited thereto, and the touch buffer layer 181 and the first touch insulating layer 183 may also overlap the crack sensing pattern CSP. The touch buffer layer 181 and the first touch insulation layer 183 may not be disposed in the bending region BR.

The second touch insulating layer 184 may overlap the first dam DI and the second dam D2. The second touch insulating layer 184 may not be disposed outside the second dam D2, but the embodiments of the present disclosure are not limited thereto.

A touch connection line 185′ may be electrically connected to the second connection electrode CNE2. The touch connection line 185′ may serve to provide a signal applied from the pad electrode PAD and the second connection electrode CNE2 to the first sensor electrode 185a or the second sensor electrode 185b described above in FIG. 3. The touch connection line 185′ may be located on the same layer as the second touch conductive layer (the first sensor electrode 185a of FIG. 3), but the embodiments of the present disclosure are not limited thereto, and the touch connection line 185′ may be located on the same layer as the first touch conductive layer (the bridge electrode 182 of FIG. 3) or formed of two first and second touch conductive layers, but the embodiments of the present disclosure are not limited thereto. As an example, the touch connection line 185′ may be located on layer different from any of the second touch conductive layer and the first touch conductive layer, without being limited thereto.

The filter insulating layer 114 may be disposed on the touch connection line 185′, and the filter insulating layer 114 may not be disposed in the bending region BR.

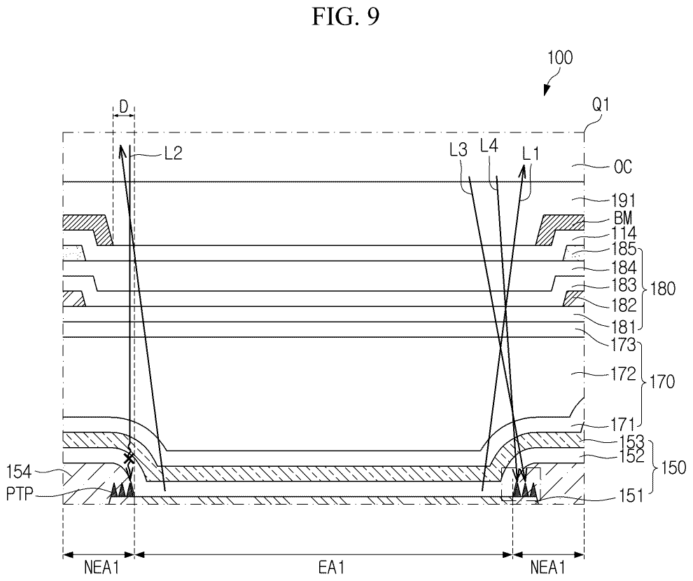

FIG. 9 is an enlarged cross-sectional view of area Q1 in FIG. 3.

Referring to FIG. 9, as an example, a distance between the end of the black matrix BM and the boundary between the first light-emitting area EA1 and the first non-light-emitting area NEA1 may be longer than a distance between the end of the bank 154 and the boundary between the first light-emitting area EA1 and the first non-light-emitting area NEA1. As an example, the end of the bank 154 may be aligned with the boundary between the first light-emitting area EA1 and the first non-light-emitting area NEA1, but the embodiments of the present disclosure are not limited thereto. In the case of the display panel 100 according to one example embodiment, the bank 154 may include a black-based material, and since the distance between the end of the black matrix BM and the boundary between the first light-emitting area EA1 and the first non-light-emitting area NEA1 may be longer than the distance between the end of the bank 154 and the boundary between the first light-emitting area EA1 and the first non-light-emitting area NEA1, first light L1 emitted from the first light-emitting area EA1 may be emitted upward with a greater viewing angle as much as a space between the end of the black matrix BM and the boundary between the first light-emitting area EA1 and the first non-light-emitting area NEA1. Accordingly, it is possible to reduce or minimize a reduction in luminance according to a viewing angle. However, when the distance between the end of the black matrix BM and the boundary between the first light-emitting area EA1 and the first non-light-emitting area NEA1 is longer than the distance between the end of the bank 154 and the boundary between the first light-emitting area EA1 and the first non-light-emitting area NEA1 and the bank 154 is formed of a transparent material, second light L2 incident from the outside may be reflected by the bank 154, resulting in visible ring-shaped spots. However, in the case of the display panel 100 according to one example embodiment, the second light L2 may be absorbed or blocked by the bank 154 including a black-based material, thereby reducing or preventing the occurrence of the ring-shaped spots.

Meanwhile, the display panel 100 according to one example embodiment may further include the optical pattern PTP in an area in which the anode electrode 151 overlaps the bank 154. The optical pattern PTP may be disposed between the upper surface of the anode electrode 151 and the bank 154. As described above, the bank 154 serves to absorb or block the second light L2, but as illustrated in FIG. 9, the thickness of the bank 154 may be smaller toward the center of the anode electrode 151. In this case, among the second light L2 of the bank 154, light L3 and L4 that is not absorbed by the bank 154 may be generated. Third and fourth light L3 and L4 transmits the bank 154 and is highly likely reflected by the anode electrode 151, and in this case, ring-shaped spots may occur.

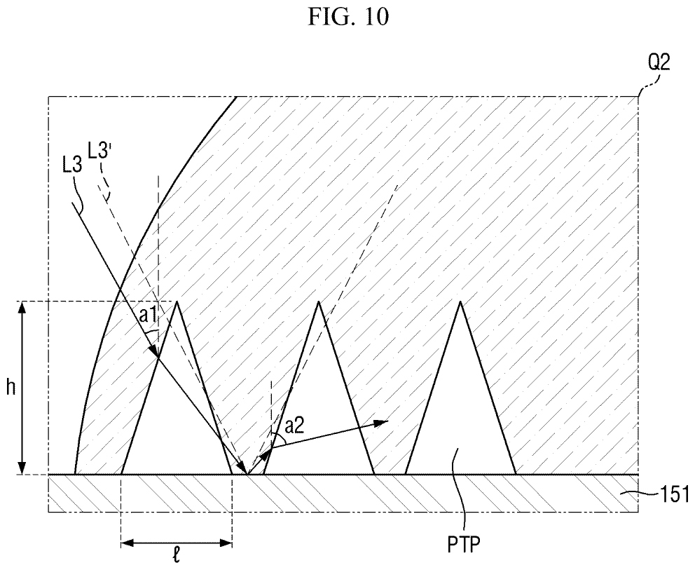

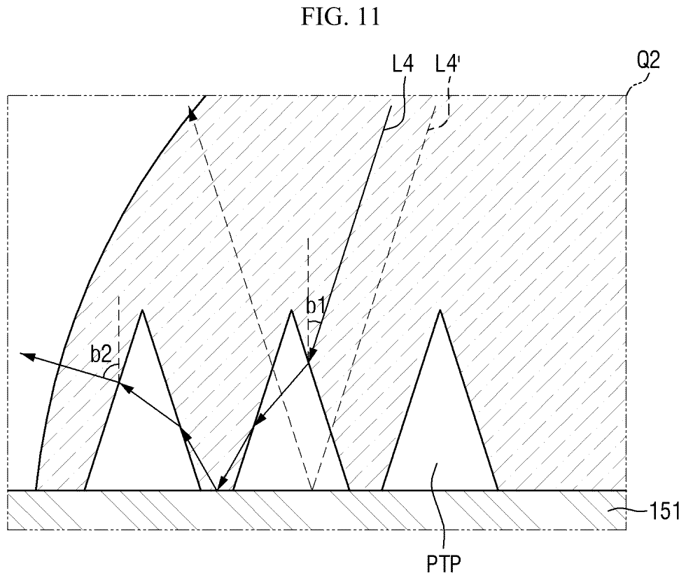

FIG. 10 is an enlarged cross-sectional view of area Q2 in FIG. 9. FIG. 11 is an enlarged cross-sectional view of area Q2 in FIG. 9. FIG. 10 illustrates light incident from the left to the right from the first light-emitting area EA1 or the first non-light-emitting area NEA1 toward the optical pattern PTP, and FIG. 11 illustrates light incident from the right to the left from the first non-light-emitting area NEA1 toward the optical pattern PTP.

As illustrated in FIGS. 9 and 10, a refractive index of the optical pattern PTP may be higher than a refractive index of the bank 154. For example, the refractive index of the bank 154 may range from about 1.5 to 1.6, and the refractive index of the optical pattern PTP may range from about 1.6 to 1.8, but the embodiments of the present disclosure are not limited thereto. The optical pattern PTP may include an organic insulation material or an inorganic insulation material. The optical pattern PTP may have a height h that is more than or equal to about 1.2 times greater than a length 1 of the bottom surface of the optical pattern PTP, but the embodiments of the present disclosure are not limited thereto. As an example, the optical pattern PTP may have a triangle shape, without being limited thereto.

When the optical pattern PTP is not present (see L3′ of FIG. 10), the third light L3′ may have an incident angle from the bank 154 to the anode electrode 151, which is equal to a reflection angle from the anode electrode 151 to the bank 154. In this case, ring-shaped spots may be visible due to the third light L3′ reflected from the anode electrode 151.

However, when the optical pattern PTP is present, since the optical pattern PTP includes a high refractive material compared to the bank 154, as illustrated in FIG. 10, the optical pattern PTP may refract the third light L3 to increase a traveling angle of the third light L3. As an example, there could be a plurality of optical patterns PTP at one end of the bank 154. For example, the traveling angle of the third light L3 initially incident on the optical pattern PTP is a1, but the traveling angle of the third light L3 reflected from the anode electrode 151 and refracted by the optical pattern PTP (e.g., another optical pattern PTP) may be a2 that is greater than a1. The traveling angle of light in the present disclosure may refer to an angle from the normal line (a line extending vertically) to a traveling direction of light. When the traveling angle of the third light L3 increases, a path of the third light L3 in the black-based bank 154 is longer, and thus the third light L3 may be highly likely absorbed in the bank 154. Accordingly, the third light L3 reflected from the anode electrode 151 can be reduced or prevented from being emitted to the outside, thereby reducing or eliminating visible ring-shaped spots.

As illustrated in FIGS. 9 and 11, when the optical pattern PTP is not present (see LA′ of FIG. 11), fourth light LA′ may have an incident angle from the bank 154 to the anode electrode 151, which is equal to a reflection angle from the anode electrode 151 to the bank 154. In this case, ring-shaped spots may be visible due to the fourth light LA′ reflected from the anode electrode 151.

However, when the optical pattern PTP is present, since the optical pattern PTP includes a high refractive material compared to the bank 154, as illustrated in FIG. 11, the optical pattern PTP may refract the fourth light LA to increase a traveling angle of the fourth light LA. For example, a traveling angle of the fourth light LA initially incident on the optical pattern PTP is b1, but the traveling angle of the fourth light LA reflected from the anode electrode 151 and refracted by the optical pattern PTP may be b2 that is greater than b1. When the traveling angle of the fourth light LA is greater than a critical viewing angle (e.g., 60°) at which light is visible by a user from the outside, the user cannot view the fourth light L4, thereby reducing or eliminating ring-shaped spots.

Hereinafter, a display device according to other example embodiments will be described. In the following example embodiments, the detailed description of the reference numerals or components described in FIGS. 1 to 11 will be omitted or briefly given, or the overlapping descriptions thereof will be omitted or briefly given.

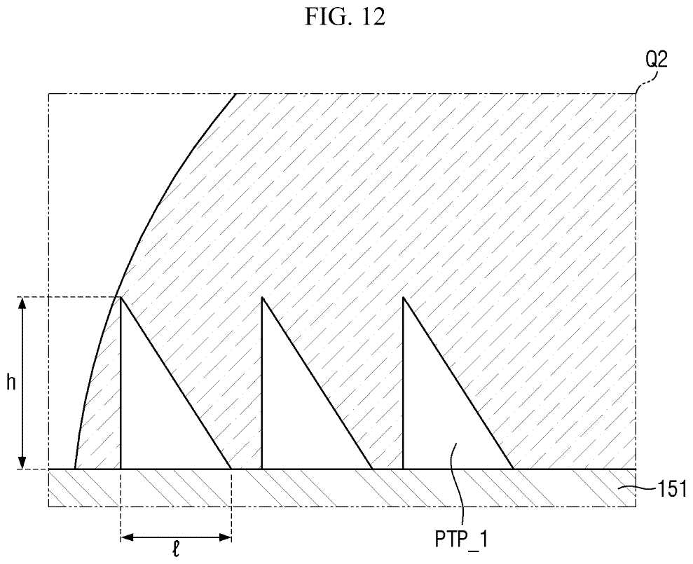

FIG. 12 is a cross-sectional view of a display device according to another example embodiment.

Referring to FIG. 12, an optical pattern PTP_1 according to the present example embodiment differs from the optical pattern PTP according to FIG. 10 in that it may have a right-angled triangle shape.

For example, the optical pattern PTP_1 may have one side surface extending vertically and the other side surface tapered vertically. As an example, the optical pattern PTP_1 may have one side surface adjacent to the end of the bank 154 extending vertically, and the other side surface facing away from end of the bank 154 tapered vertically, vice versa. As an example, there may be a plurality of the optical patterns PTP_1, which have the same shape or different shapes, and/or the same size or different sizes. As an example, the side surfaces of the plurality of optical pattern PTP_1 extending vertically may face the same direction or different directions, without being limited thereto.

Even in the present example embodiment, by including the optical pattern PTP_1 including a high refractive material compared to the bank 154, it is possible to reduce or prevent ring-shaped spots from being visible.

Since the remaining parts have been described above in FIGS. 10 to 12, the detailed descriptions thereof will be omitted or briefly given below.

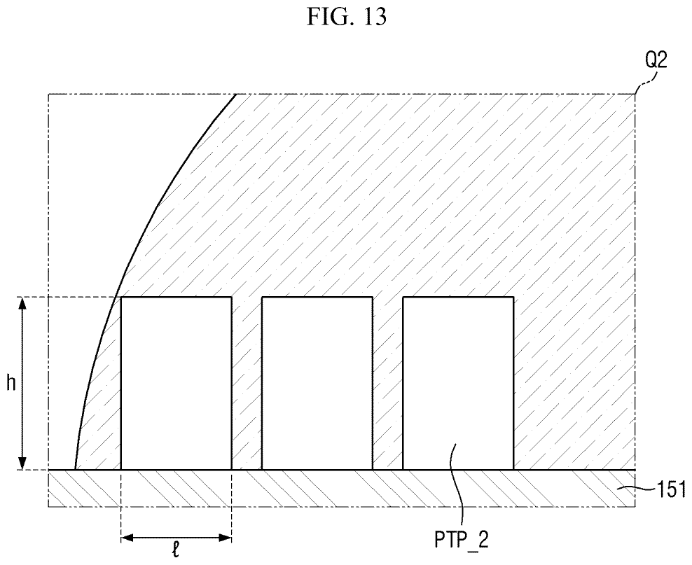

FIG. 13 is a cross-sectional view of a display device according to another example embodiment.

Referring to FIG. 13, an optical pattern PTP_2 according to the present example embodiment differs from the optical pattern PTP according to FIG. 10 in that it may have a rectangle shape.

Even in the present example embodiment, by including the optical pattern PTP_2 including a high refractive material compared to the bank 154, it is possible to reduce or prevent ring-shaped spots from being visible.

Since the remaining parts have been described above in FIGS. 10 to 12, the detailed descriptions thereof will be omitted or briefly given below.

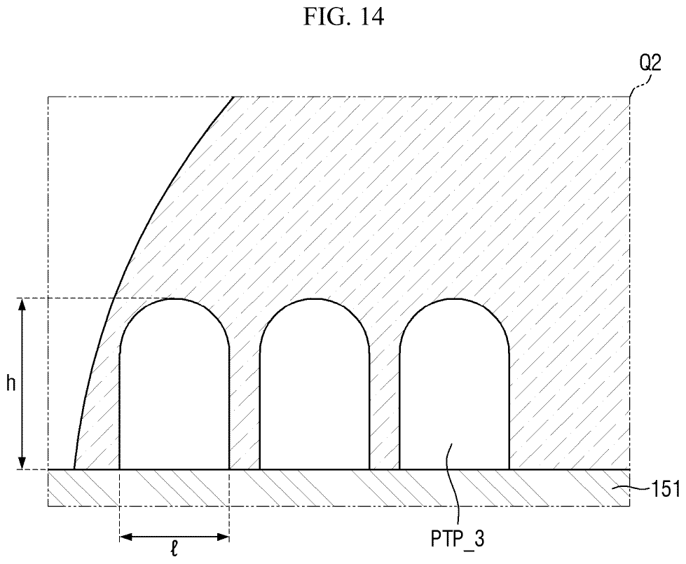

FIG. 14 is a cross-sectional view of a display device according to another example embodiment.

Referring to FIG. 14, an optical pattern PTP_3 according to the present example embodiment differs from the optical pattern PTP_2 according to FIG. 13 in that it may have a curved upper end portion.

Even in the present example embodiment, by including the optical pattern PTP_3 including a high refractive material compared to the bank 154, it is possible to reduce or prevent ring-shaped spots from being visible.

Since the remaining descriptions are as described above in FIG. 13, the detailed descriptions thereof will be omitted or briefly given.

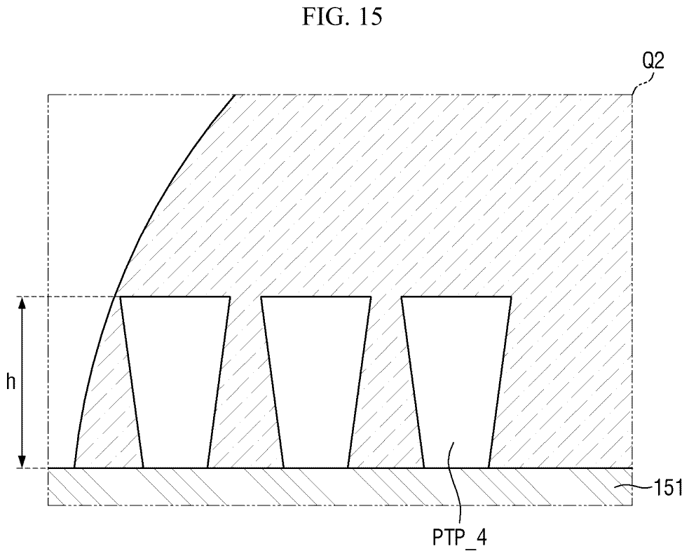

FIG. 15 is a cross-sectional view of a display device according to another example embodiment.

Referring to FIG. 15, an optical pattern PTP_4 according to the present example embodiment differs from the optical pattern PTP according to FIG. 10 in that it may have an inversely-tapered trapezoid shape.

Even in the present example embodiment, by including the optical pattern PTP_4 including a high refractive material compared to the bank 154, it is possible to reduce or prevent ring-shaped spots from being visible.

Since the remaining parts have been described above in FIGS. 10 to 12, the detailed descriptions thereof will be omitted below or briefly given.

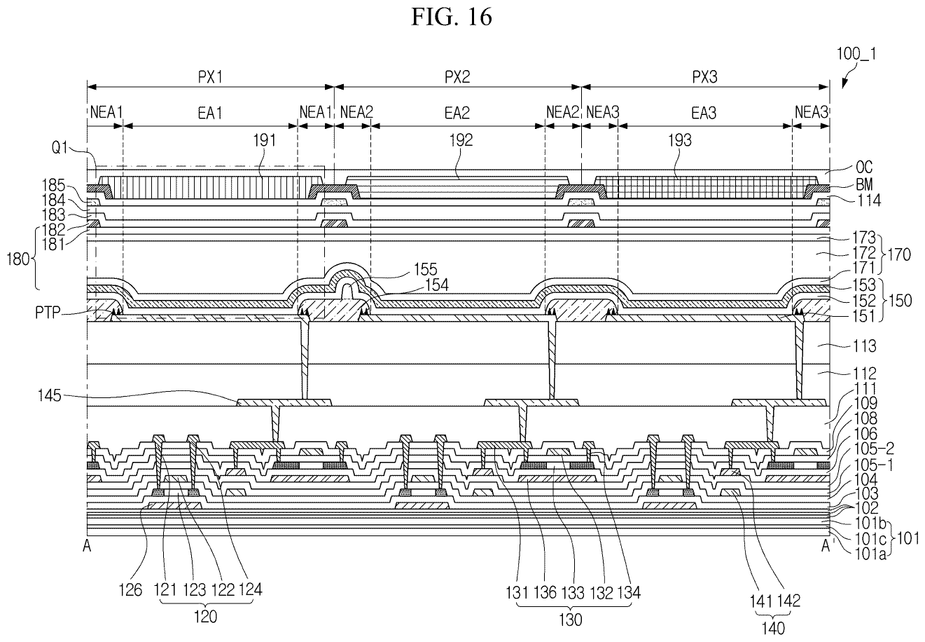

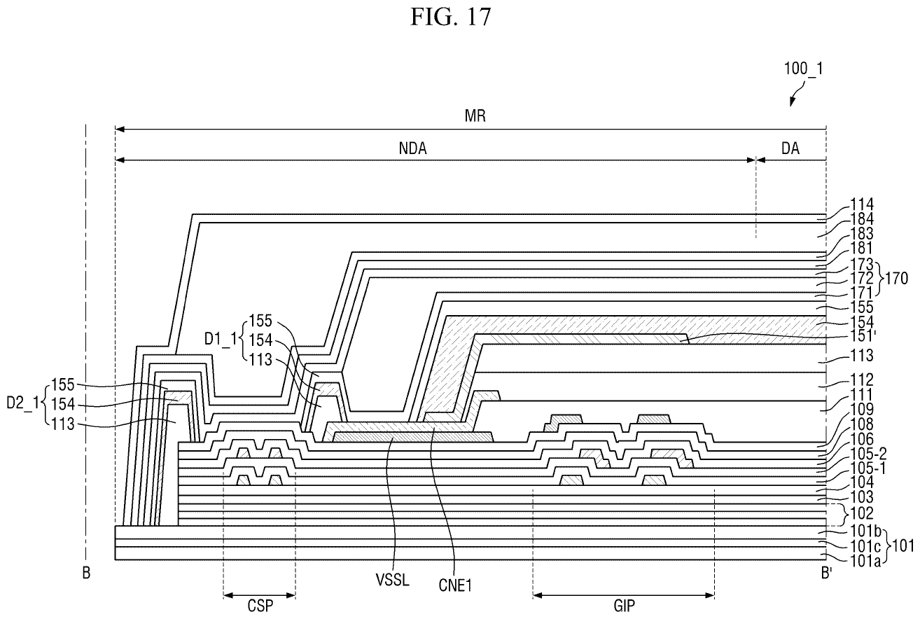

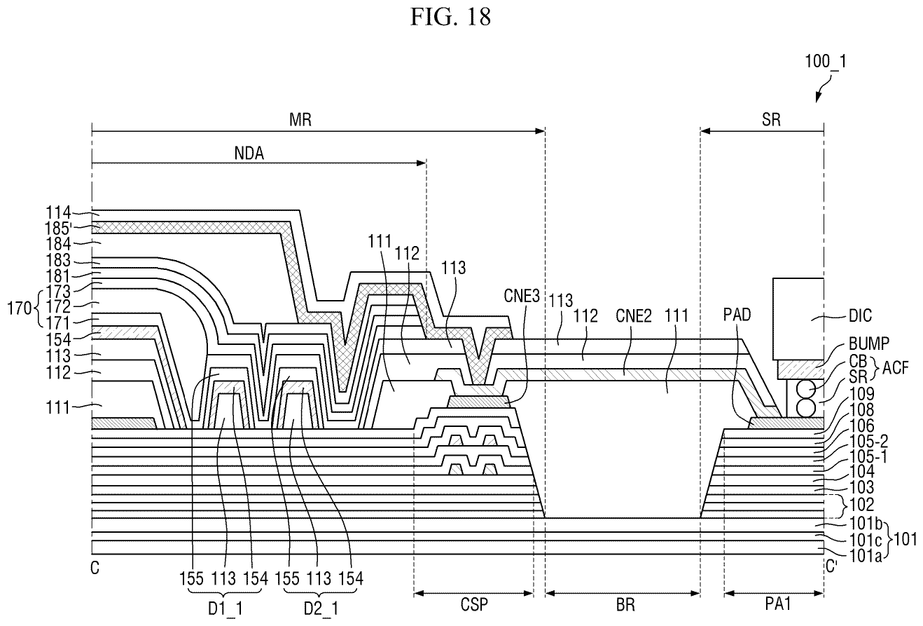

FIG. 16 is a cross-sectional view of a display device according to still another example embodiment. FIG. 17 is a cross-sectional view of a display device according to still another example embodiment. FIG. 18 is a cross-sectional view of a display device according to still another example embodiment.

Referring to FIGS. 16 to 18, a display panel 100_1 of the display device according to the present example embodiment differs from the display panel 100 according to FIGS. 3, 7, and 8 in that it may further include a third protective layer 113 on the second protective layer 112.

More specifically, the display panel 100_1 according to the present example embodiment may further include the third protective layer 113 between the second protective layer 112 and the anode electrode 151. A material of the third protective layer 113 may include at least one of materials exemplified as the material of the second protective layer 112, but the embodiments of the present disclosure are not limited thereto.

As illustrated in FIGS. 17 and 18, each of a first dam D1_1 and a second dam D2_1 may include the third protective layer 113 as a first layer and may not include the second protective layer 112, but the embodiments of the present disclosure are not limited thereto.

Since the remaining parts have been described above in FIGS. 3, 7, and 8, the detailed descriptions thereof will be omitted below or briefly given.

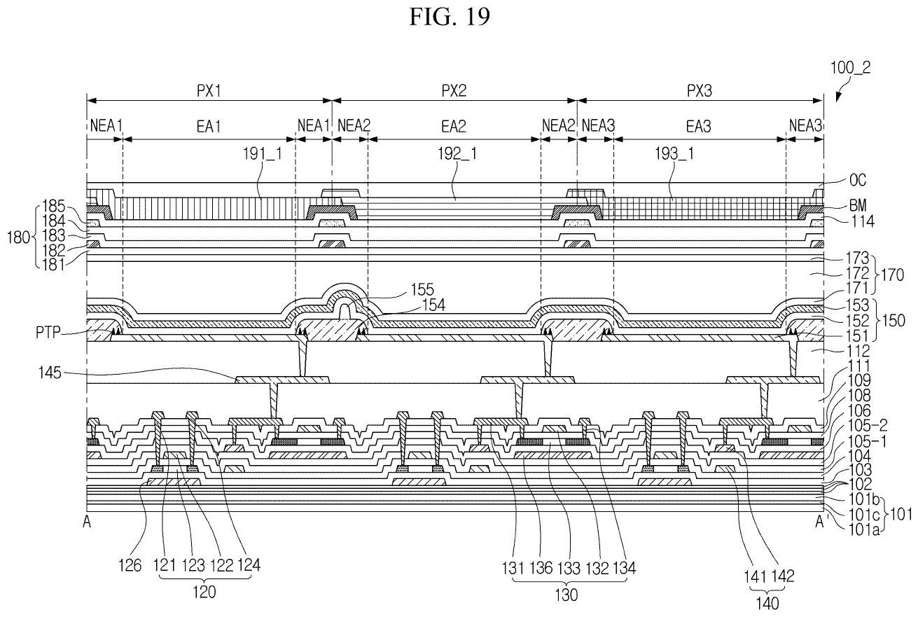

FIG. 19 is a cross-sectional view of a display device according to another example embodiment.

Referring to FIG. 19, color filters 191_1, 192_1, and 193_1 of a display panel 100_2 of the display device according to the present example embodiment differ from the display panel 100 according to FIG. 3 in that they may overlap each other in the non-light-emitting areas NEA1, NEA2, and NEA3.

FIG. 19 illustrates that a second color filter 192_1 is located at the top, a first color filter 191_1 is located under the second color filter 192_1, and lastly a third color filter 193_1 is located at the bottom in each non-light-emitting area NEA1, NEA2, or NEA3, but the stacking order of each color filter 191_1, 192_1, or 193_1 in the non-light-emitting areas NEA1, NEA2, and NEA3 may vary according to a process order.

Since the remaining parts have been described above in FIG. 3, the detailed descriptions thereof will be omitted or briefly given.

A display device according to various example embodiments of the present disclosure may be described as follows.

A display device according to example embodiments of the present disclosure includes a substrate, a display area including a plurality of sub-pixels, a non-display area outside the display area, an anode electrode disposed on the substrate and located in each of the plurality of sub-pixels, a bank disposed on the anode electrode, located at a boundary between adjacent sub-pixels, and overlapping a periphery of an upper surface of the anode electrode, and an optical pattern disposed between the periphery of the upper surface of the anode electrode and the bank, in which the bank includes a black-based material.

In the display device according to the example embodiments of the present disclosure, the optical pattern may come into direct contact with the bank.

In the display device according to the example embodiments of the present disclosure, a refractive index of the optical pattern may be greater than a refractive index of the bank.

In the display device according to the example embodiments of the present disclosure, the plurality of sub-pixels may include a first sub-pixel, a second sub-pixel, and a third sub-pixel and further include an organic layer disposed on the bank.

In the display device according to the example embodiments of the present disclosure, the organic layer may include a first light-emitting layer on the first sub-pixel, a second light-emitting layer on the second sub-pixel, and a third light-emitting layer on the third sub-pixel.

In the display device according to the example embodiments of the present disclosure, each of the first light-emitting layer, the second light-emitting layer, and the third light-emitting layer may be stacked in two or more layers.

The display device according to the example embodiments of the present disclosure may further include a cathode electrode on the organic layer, and a black matrix located at the boundary between the adjacent sub-pixels on the cathode electrode, in which a width of the black matrix may be smaller than a width of the bank.

In the display device according to the example embodiments of the present disclosure, an end of the black matrix may be closer to the boundary between the adjacent sub-pixels than an end of the bank.

The display device according to the example embodiments of the present disclosure may further include a touch part on the cathode electrode, in which the touch part may include a bridge electrode, and a sensor electrode on the bridge electrode, and the black matrix may overlap the bridge electrode and the sensor electrode.

The display device according to the example embodiments of the present disclosure may further include a color filter on the touch part and the black matrix, in which the color filter may include a first color filter on the first sub-pixel, a second color filter on the second sub-pixel, and a third color filter on the third sub-pixel.

In the display device according to the example embodiments of the present disclosure, the first color filter, the second color filter, and the third color filter may overlap each other at the boundaries between the sub-pixels.

The display device according to the example embodiments of the present disclosure may further include a first transistor between the substrate and the anode electrode, and a second transistor between the first transistor and the anode electrode.

The display device according to the example embodiments of the present disclosure may further include a first protective layer between the second transistor and the anode electrode, a first connection electrode disposed on the first protective layer, and a second protective layer on the first connection electrode, in which the first connection electrode may electrically connect the second transistor to the anode electrode.

In the display device according to the example embodiments of the present disclosure, a semiconductor layer of the first transistor may include polysilicon, and a semiconductor layer of the second transistor may include oxide.

In the display device according to the example embodiments of the present disclosure, the non-light-emitting area may include a low-potential voltage line, and a gate driving unit between the low-potential voltage line and the display area.

In the display device according to the example embodiments of the present disclosure, the non-display area may further include a crack sensing pattern outside the low-potential voltage line, and a dam overlapping the low-potential voltage line.

A display device according to example embodiments of the present disclosure includes a substrate, a display area including a plurality of sub-pixels, a non-display area outside the display area, an anode electrode disposed on the substrate and located in each of the plurality of sub-pixels, a bank disposed on the anode electrode, located at a boundary between adjacent sub-pixels, and overlapping a periphery of an upper surface of the anode electrode, an organic layer disposed on the anode electrode and the bank, a cathode electrode on the organic layer, an encapsulation part on the cathode electrode, a touch part disposed on the encapsulation part and including a first touch conductive layer having a bridge electrode, and a second touch conductive layer having a sensor electrode and disposed on the first touch conductive layer, and a black matrix disposed at a boundary between the adjacent sub-pixels on the touch part and covering the bridge electrode and the sensor electrode, in which a width of the black matrix is smaller than a width of the bank, and the display device may further include an optical pattern disposed between the periphery of the upper surface of the anode electrode and the bank.

In the display device according to the example embodiments of the present disclosure, an end of the black matrix may be closer to the boundary between the adjacent sub-pixels than an end of the bank.

In the display device according to the example embodiments of the present disclosure, the optical pattern may come into direct contact with the bank.

In the display device according to the example embodiments of the present disclosure, a refractive index of the optical pattern may be greater than a refractive index of the bank.

In the display device according to the example embodiments of the present disclosure, the optical pattern including a higher refraction material than the bank can be formed on the upper surface of the anode electrode overlapping the bank to guide external light reflected from the anode electrode to the bank.

In the display device according to the example embodiments of the present disclosure, the bank can include the black-based material to absorb external light guided to the bank.

In the display device according to the example embodiments of the present disclosure, external light can be guided to the bank and absorbed, thereby reducing the reflectance due to the anode electrode. Accordingly, the low-power display device can be implemented.

In the display device according to the example embodiments, external light can be guided to the bank and absorbed, thereby preventing annular spots from occurring in the area in which the anode electrode overlaps the bank (or a part of the non-light-emitting area).

However, effects obtainable from the present disclosure are not limited to the above-described effects, and other effects that are not mentioned will be able to be clearly understood by those skilled in the art to which the present disclosure pertains from the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

What is claimed is:

1. A display device, comprising:
a substrate;
a display area including a plurality of sub-pixels;
a non-display area outside the display area;
an anode electrode disposed on the substrate and located in each of the plurality of sub- pixels;
a bank disposed on the anode electrode, located at a boundary between adjacent sub-pixels, and overlapping a periphery of an upper surface of the anode electrode; and
an optical pattern disposed between the periphery of the upper surface of the anode electrode and the bank,
wherein the bank includes a black-based material.

2. The display device of claim 1, wherein the optical pattern comes into direct contact with the bank.

3. The display device of claim 1, wherein a refractive index of the optical pattern is greater than a refractive index of the bank.

4. The display device of claim 1, wherein the plurality of sub-pixels include a first sub-pixel, a second sub-pixel, and a third sub-pixel and further include an organic layer disposed on the bank.

5. The display device of claim 4, wherein the organic layer includes a first light-emitting layer on the first sub-pixel, a second light-emitting layer on the second sub-pixel, and a third light-emitting layer on the third sub-pixel.

6. The display device of claim 5, wherein each of the first light-emitting layer, the second light-emitting layer, and the third light-emitting layer is stacked in two or more layers.

7. The display device of claim 4, further comprising: a cathode electrode on the organic layer; and a black matrix located at the boundary between the adjacent sub-pixels on the cathode electrode, wherein a width of the black matrix is smaller than a width of the bank.

8. The display device of claim 7, wherein an end of the black matrix is closer to the boundary between the adjacent sub-pixels than an end of the bank.

9. The display device of claim 7, further comprising a touch part on the cathode electrode, wherein the touch part includes a bridge electrode, and a sensor electrode on the bridge electrode, and wherein the black matrix overlaps the bridge electrode and the sensor electrode.

10. The display device of claim 9, further comprising a color filter on the touch part and the black matrix, wherein the color filter includes a first color filter on the first sub-pixel, a second color filter on the second sub-pixel, and a third color filter on the third sub-pixel.

11. The display device of claim 10, wherein the first color filter, the second color filter, and the third color filter overlap each other at the boundaries between the sub-pixels.

12. The display device of claim 1, further comprising: a first transistor and a second transistor between the substrate and the anode electrode.

13. The display device of claim 12, further comprising: a first protective layer between the second transistor and the anode electrode; a first connection electrode disposed on the first protective layer; and a second protective layer on the first connection electrode, wherein the first connection electrode electrically connects the second transistor to the anode electrode.

14. The display device of claim 12, wherein a semiconductor layer of the first transistor includes polysilicon, and a semiconductor layer of the second transistor includes oxide.

15. The display device of claim 1, wherein the non-display area includes a low- potential voltage line, and a gate driving unit between the low-potential voltage line and the display area.

16. The display device of claim 15, wherein the non-display area further includes a crack sensing pattern outside the low-potential voltage line, and a dam overlapping the low-potential voltage line.

17. The display device of claim 1, wherein the optical pattern is formed directly on the upper surface of the anode electrode.

18. The display device of claim 1, wherein the optical pattern is not formed outside the bank.

19. The display device of claim 1, wherein the optical pattern includes an insulation material.

20. The display device of claim 1, wherein the optical pattern has a triangle shape, a rectangle shape, a shape with a curved upper end portion, or an inversely-tapered trapezoid shape.

21. The display device of claim 20, the optical pattern has the triangle shape, which has a height that is more than or equal to 1.2 times greater than a length of a bottom surface of the triangle shape.

22. The display device of claim 20, the optical pattern has a right-angled triangle shape.

23. The display device of claim 20, wherein a plurality of optical patterns is disposed between the periphery of the upper surface of the anode electrode and the bank.

24. The display device of claim 20, wherein the optical pattern is configured to refract a light transmitting into the bank to increase a traveling angle of the light with respect to a normal line for an upper surface of the substrate.

25. The display device of claim 23, wherein, with respect to a normal line for an upper surface of the substrate, a light transmitting into the bank is incident on one optical pattern of the plurality of optical patterns with a first traveling angle, reflected from the anode electrode, and is refracted by another optical pattern of the plurality of optical patterns to have a second traveling angle.

26. The display device of claim 25, wherein the second traveling angle is greater than the first traveling angle.

27. A display device, comprising:
a substrate;
a display area including a plurality of sub-pixels;
a non-display area outside the display area;
an anode electrode disposed on the substrate and located in each of the plurality of sub-pixels;
a bank disposed on the anode electrode, located at a boundary between adjacent sub-pixels, and overlapping a periphery of an upper surface of the anode electrode;
an organic layer disposed on the anode electrode and the bank;
a cathode electrode on the organic layer;
an encapsulation part on the cathode electrode;
a touch part disposed on the encapsulation part, a first touch conductive layer having a bridge electrode, and a second touch conductive layer having a sensor electrode and disposed on the first touch conductive layer; and
a black matrix disposed at the boundary between the adjacent sub-pixels on the touch part and covering the bridge electrode and the sensor electrode,
wherein:
a width of the black matrix is smaller than a width of the bank; and
the display device further includes an optical pattern disposed between the periphery of the upper surface of the anode electrode and the bank.

28. The display device of claim 27, wherein an end of the black matrix is closer to the boundary between the adjacent sub-pixels than an end of the bank.

29. The display device of claim 27, wherein the optical pattern comes into direct contact with the bank.

30. The display device of claim 27, wherein a refractive index of the optical pattern is greater than a refractive index of the bank.
